(19) United States
(12) Patent Application Publication
(10) Pub. No.: US 2023/0022058 A1
(43) Pub. Date: Jan. 26, 2023

(54) BACK PLATES TO SUPPORT INTEGRATED CIRCUIT PACKAGES IN SOCKETS ON PRINTED CIRCUIT BOARDS AND ASSOCIATED METHODS

(71) Applicant: Intel Corporation, Santa Clara, CA (US)

(72) Inventors: Phil Geng, Washougal, WA (US); Ralph Miele, Hillsboro, OR (US); David Shia, Portland, OR (US)

(21) Appl. No.: 17/956,540

(22) Filed: Sep. 29, 2022

(51) Int. Cl. H05K 1/03; H05K 3/46; H05K 3/00

(52) U.S. Cl. CPC H05K 1/0306; H05K 3/4644; H05K 3/0014; H05K 2201/09063; H05K 2201/10325; H01L 23/3735

(57) ABSTRACT

Back plates to support integrated circuit packages in sockets on printed circuit boards and associated methods are disclosed. An example back plate includes a ceramic substrate having a first surface and a second surface opposite the first surface. The example back plate further includes metal coupled to the ceramic substrate. At least a portion of the metal is disposed between planes defined by the first and second surfaces of the ceramic substrate.

### FIELD OF THE DISCLOSURE

This disclosure relates generally to integrated circuit packages and, more particularly, to back plates to support integrated circuit packages in sockets on printed circuit boards and associated methods.

### BACKGROUND

The demand for greater computing power and faster computing times continues to grow. This has led to higher-density connectors on computer hardware components to transfer signals more quickly. Some processor chips (e.g., a land grid array (LGA) processor chip, a ball grid array (BGA) processor chip, a pin grid array (PGA) processor chip, etc.) are communicatively coupled to printed circuit boards (PCBs) via sockets constructed to receive and electrical couple to contacts on the processor chips. Often a heatsink is mechanically and thermally coupled to the processor chip on a side opposite the socket to facilitate the dissipation of heat generated by the processor chip.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 is an exploded view of a known IC package heat dissipating component stack that may be modified in accordance with teachings disclosed herein.

FIG. 18 is a simplified cross-sectional view of the component stack of FIG. 17.

FIG. 19 is a plane view of an example ceramic substrate constructed in accordance with teachings disclosed herein.

FIG. 20 is a plane view of an example back plate that includes the example substrate of FIG. 19.

FIG. 21 is a cross-sectional view of the example back plate of FIG. 20 taken along the line 21-21 of FIG. 20.

FIG. 22 is a plane view of another example ceramic substrate constructed in accordance with teachings disclosed herein.

FIG. 23 is a plane view of another example back plate that includes the example substrate of FIG. 22.

FIG. 24 is a cross-sectional view of the example back plate of FIG. 23 taken along the line 24-24 of FIG. 23.

FIG. 25 is a plane view of another example back plate constructed in accordance with teachings disclosed herein.

FIG. 26 is a cross-sectional view of the example back plate of FIG. 25 taken along the line 26-26 of FIG. 25.

FIG. 27 is a perspective view of the example back plate of FIGS. 25 and 26 with example studs connected thereto.

FIG. 28 is a cross-sectional view of another example back plate constructed in accordance with teachings disclosed herein.

FIG. 29 is a cross-sectional view of another example back plate constructed in accordance with teachings disclosed herein.

FIG. 30 is a cross-sectional view of another example back plate constructed in accordance with teachings disclosed herein.

FIG. 31 is a flowchart representative of an example method of manufacturing any of the example back plates of FIGS. 19-30.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

### DETAILED DESCRIPTION

Integrated circuit (IC) packages, such as central processing units (CPUs) or other processor chips, are often coupled to printed circuit boards (PCBs) via sockets. Many sockets, including land grid array (LGA) sockets, include a plurality of pins that receive and electrically couple to corresponding features (e.g., contacts or lands) of the IC package. To ensure that the IC package is able to communicate with the circuit board, the pins of the socket must remain in contact with the IC package. In many examples, the contact force between the pins of the socket and the IC package is provided by one or more fasteners coupled between a heat sink, disposed on the IC package (e.g., opposite the socket), and a back plate disposed on an opposite side of the printed circuit board relative to the socket and IC package. Such assemblies of components are referred to herein as IC package heat dissipating component stacks. The fasteners that secure such component stacks together with sufficient compressive force to ensure electrical contact between the socket and IC package can cause warpage or bending of the back plate, the printed circuit board, and/or other components in the component stack. Such bending or warpage can reduce the contact force in particular areas of the socket. In recent years, the pin density of sockets and associated required contact force have increased to compensate for the greater processing power of IC packages. Accordingly, the back plate warpage can reduce the performance of the IC package due to the reduced contact between the IC package and the printed circuit board.

Examples disclosed herein improve pin contact between the sockets of printed circuit boards and the associated IC packages by increasing the stiffness of the back plate. An increased stiffness in the back plate provide greater support to resist the forces giving rise to bending or warpage of the back plate and other connected components in a heat dissipating component stack. More particularly, in some examples, a ceramic material, such as alumina, is used for the back plate instead of more traditional steel back plates because alumina has a greater stiffness than steel. However, ceramic materials are typically more prone to cracks or fractures, especially under shock loads. Accordingly, examples disclosed herein integrate metal with a base ceramic substrate to reinforce the ceramic and provide greater structural integrity while still taking advantage of the higher stiffness of the ceramic substrate.

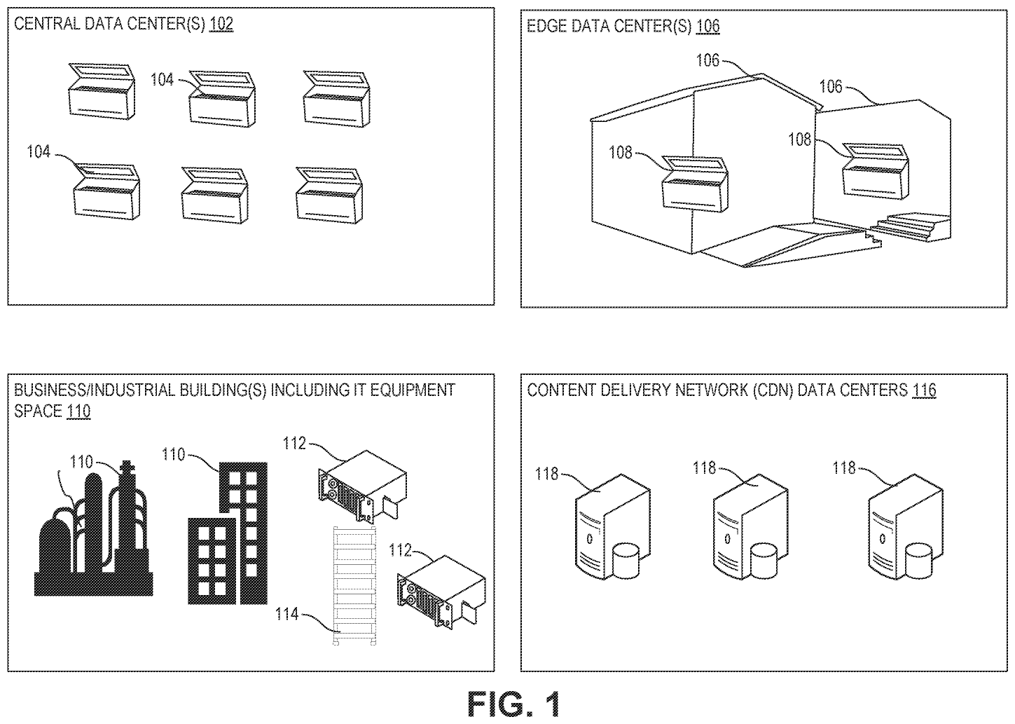

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase immersion cooling or two-phase immersion cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

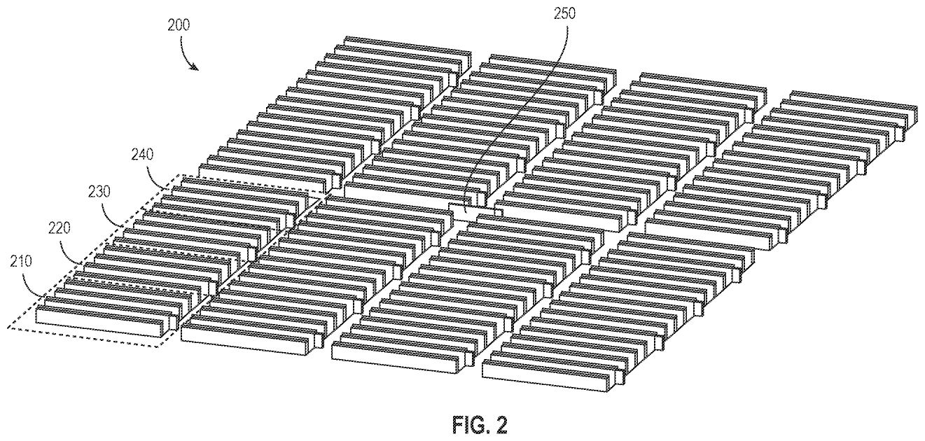

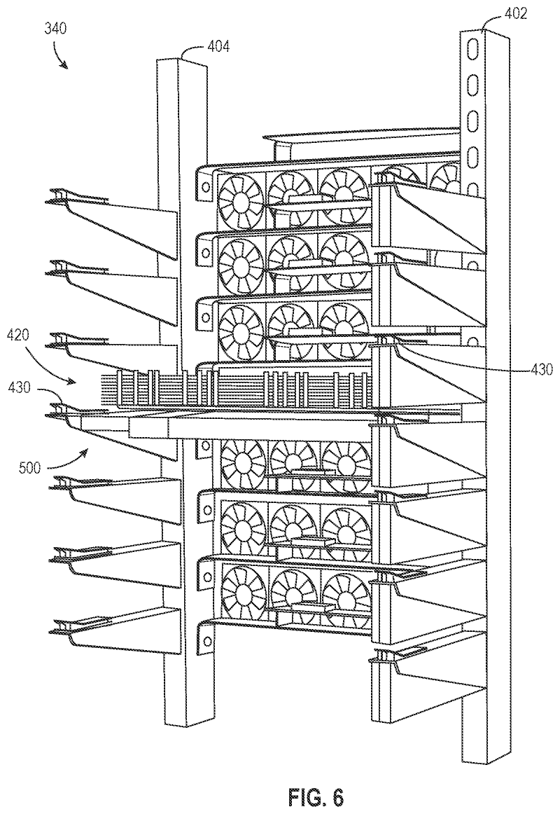

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

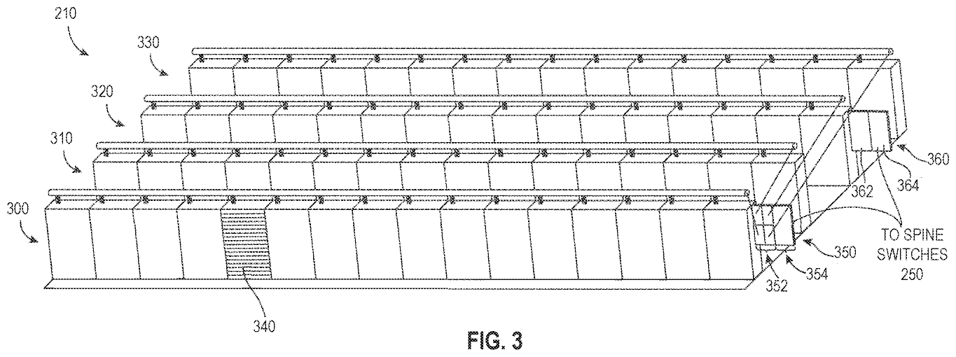

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

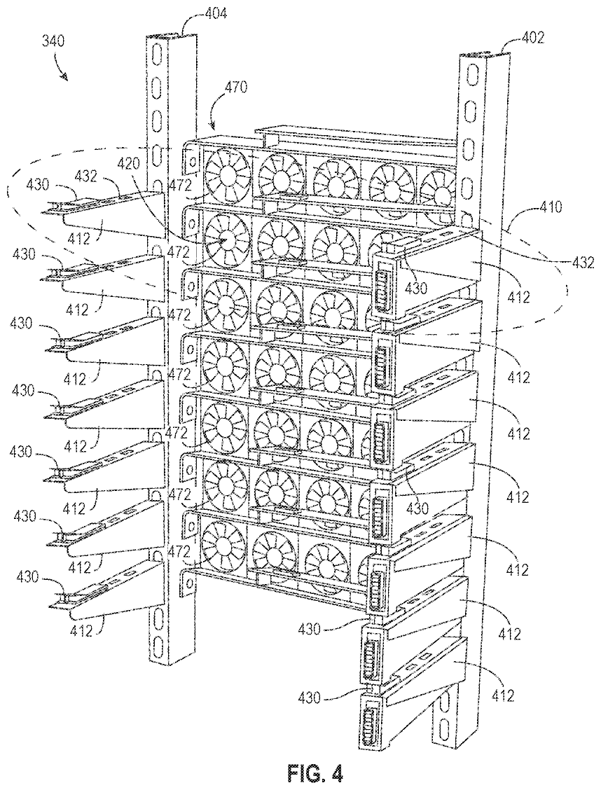

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

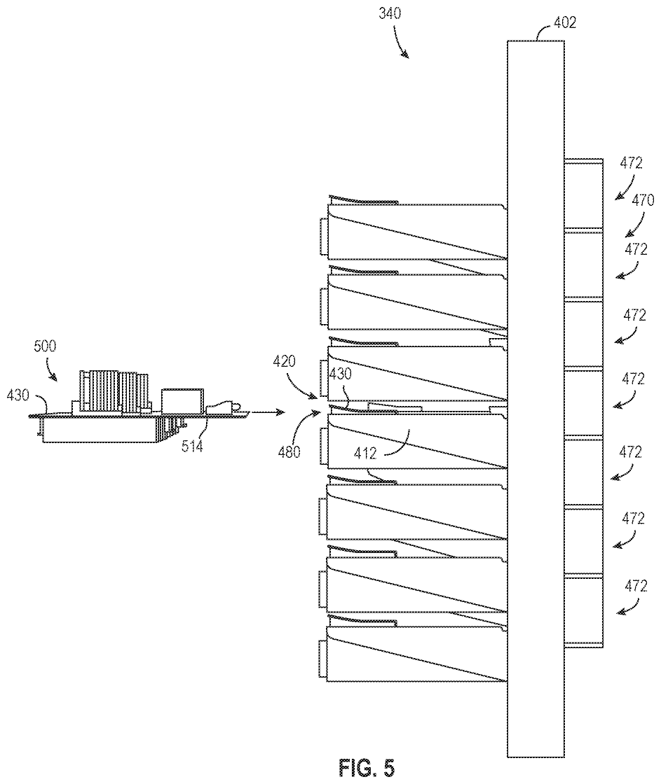

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

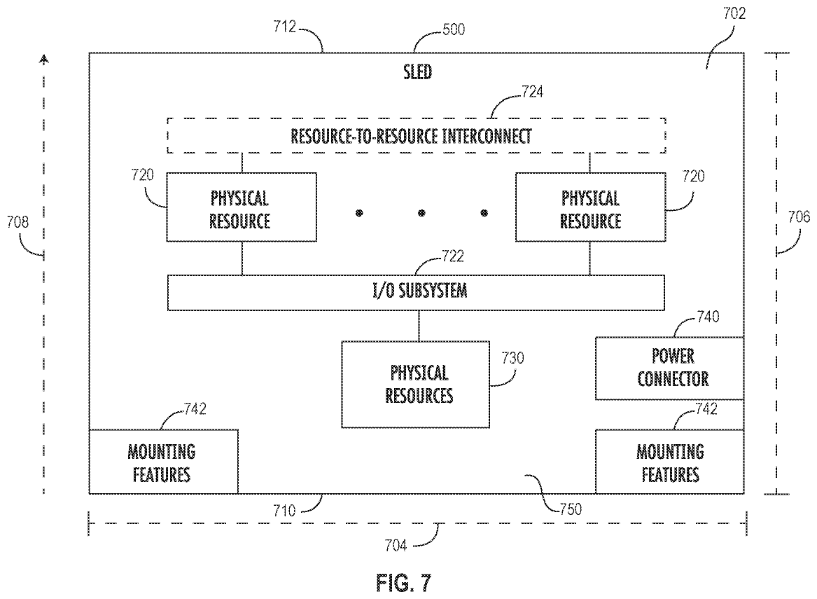

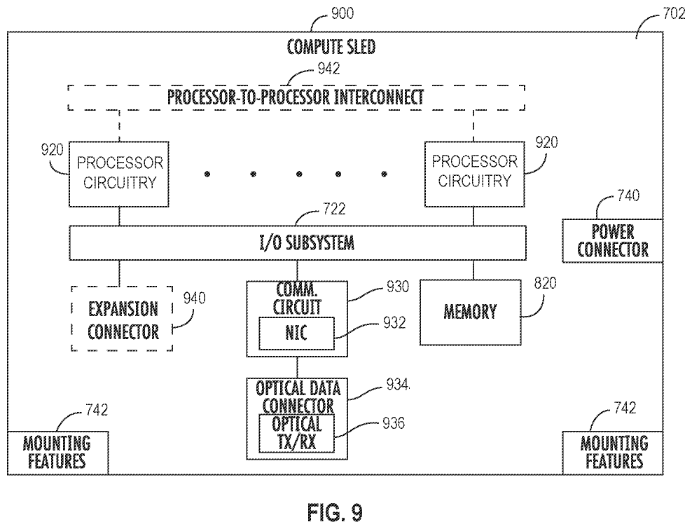

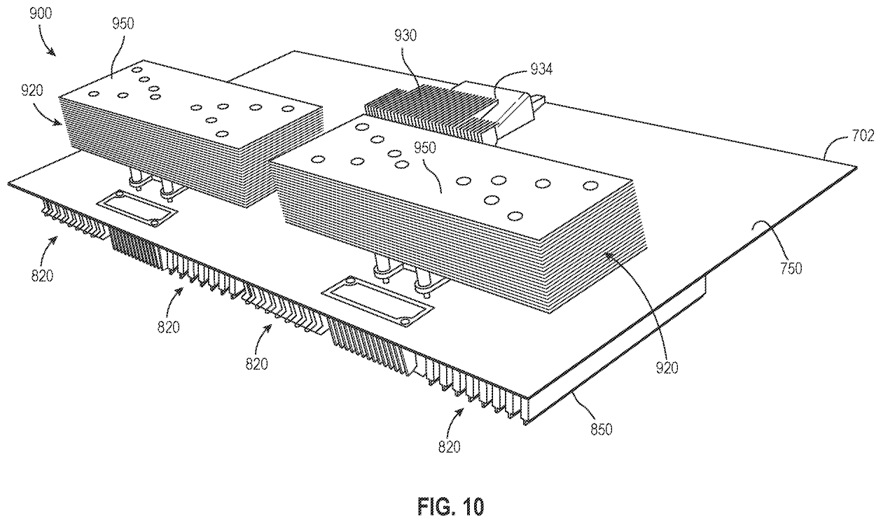

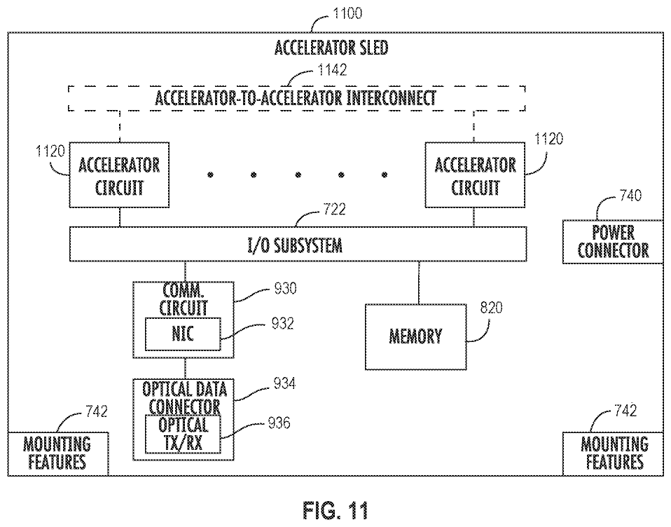

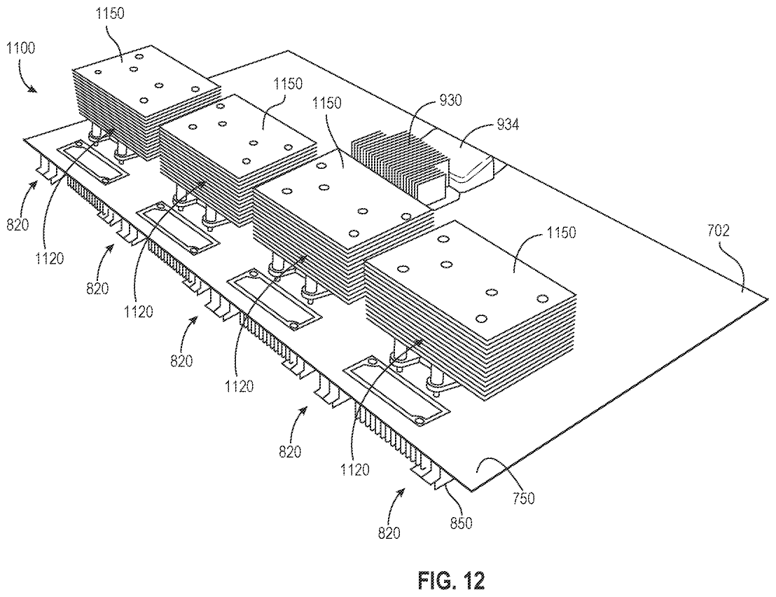

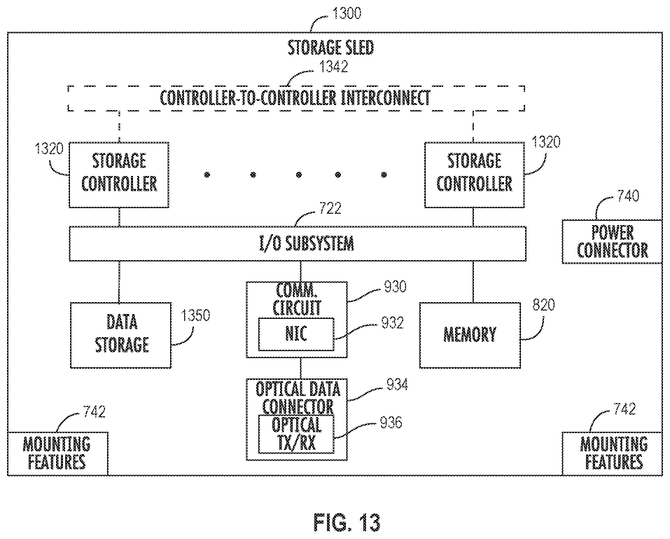

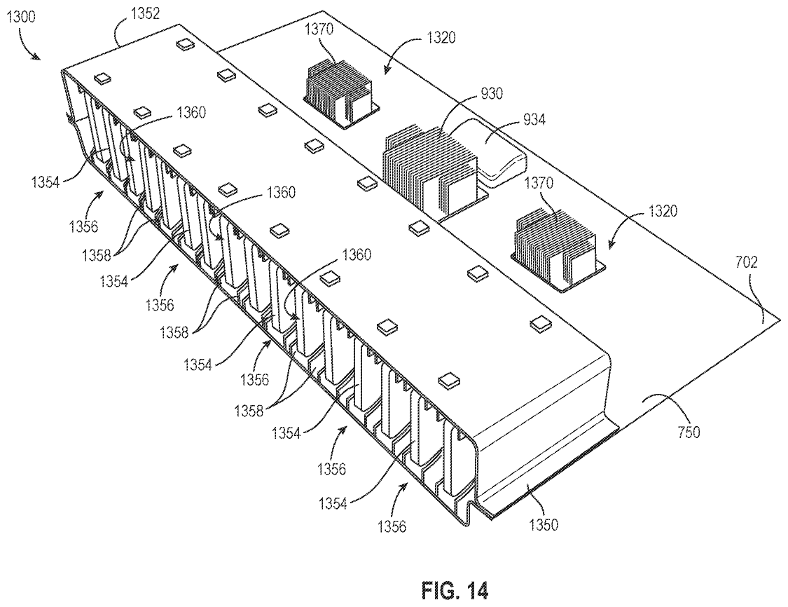

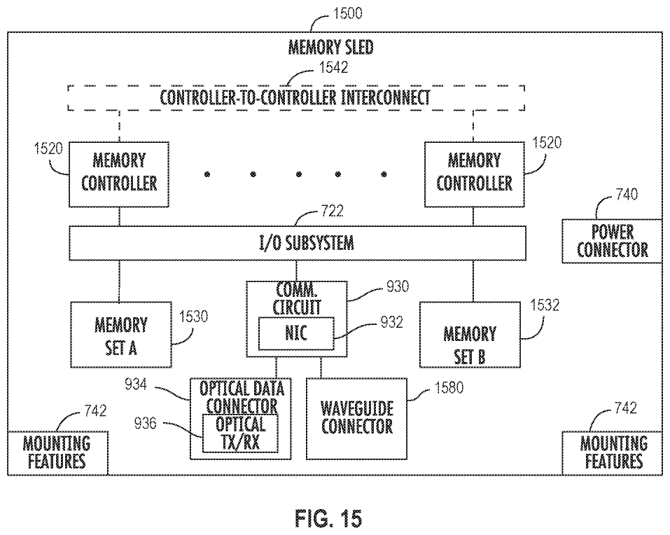

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase immersion cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDRS data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

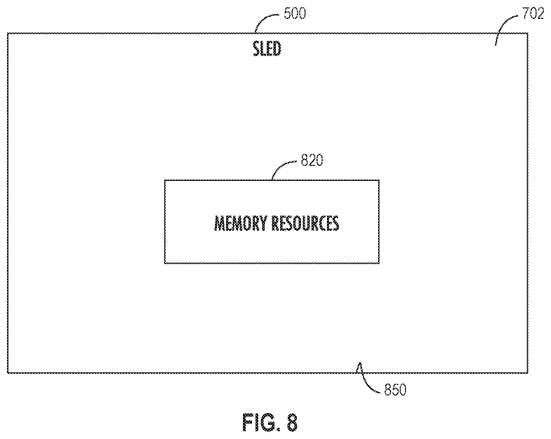

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

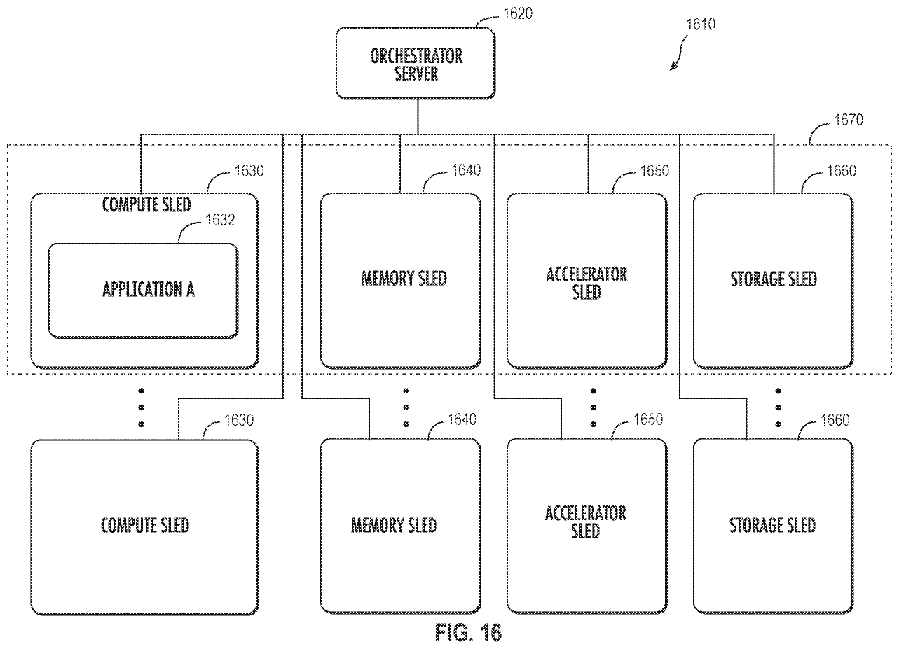

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

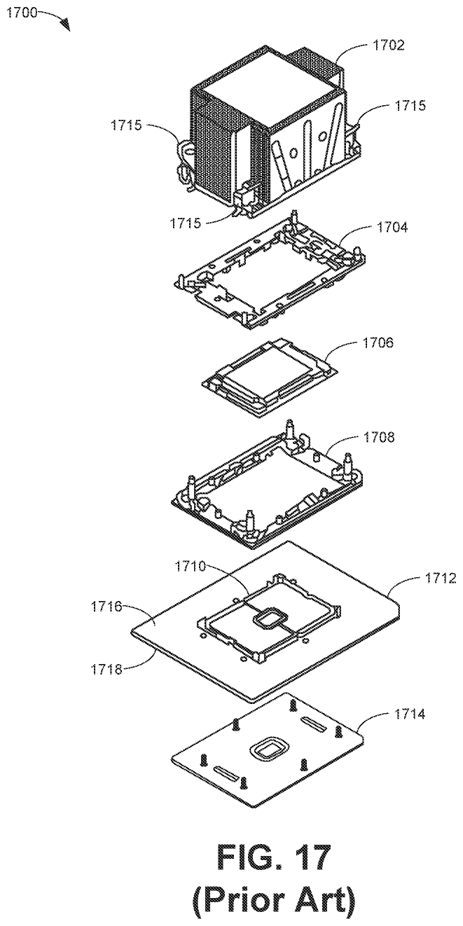

FIG. 17 illustrates an exploded view of a known integrated circuit (IC) package heat dissipating component stack 1700 that may be modified in accordance with teachings disclosed herein. In FIG. 17, the component stack 1700 includes a heatsink 1702, a carrier (e.g., a package carrier, a carrier plate) 1704, an integrated circuit (IC) package 1706, a bolster plate 1708, a socket 1710 coupled to a printed circuit board (PCB) (e.g., a motherboard) 1712, and a back plate 1714.

The IC package 1706 can include one or more electrical circuits on a semiconductor substrate. The integrated circuit 1706 can perform processing functions, memory functions, and/or any other suitable functions. The integrated circuit 1706 can include any type of processing circuitry, including programmable microprocessors, one or more FPGAs, one or more CPUs, one or more GPUs, one or more DSPs, one or more XPUs, one or more ASICs, and/or one or more microcontrollers. In FIG. 17, the IC package 1706 is a land grid array (LGA) processor chip. Additionally or alternatively, the IC package 1706 can be one of a ball grid array (BGA) processor chip or a pin grid array (PGA) processor chip instead. Further, other types of IC packages can be used in the component stack 1700 instead of a processor chip (e.g., a memory chip). In FIG. 17, the carrier 1704 is used to couple the heatsink 1702 to the IC package 1706 prior to assembly of the entire component stack 1700.

In FIG. 17, the heatsink 1702 is couplable (e.g., thermally couplable) to the IC package 1706 to dissipate heat therefrom. In some cases, the heatsink 1702 corresponds to one of the heatsinks 950 of FIG. 10, one of the heatsinks 1150 of FIG. 12, or one of the heatsinks 1370 of FIG. 14. In FIG. 17, the heatsink 1702 is mechanically coupled to the back plate 1714 via fixture elements, loading mechanisms, or fasteners 1715 to place the components between the heatsink 1702 and the back plate 1714 within the component stack 1700 in compression when assembled. In some examples, the heatsink 1702 is coupled to the back plate 1714 via the bolster plate 1708 positioned therebetween. More particularly, as shown in FIG. 17, the bolster plate 1708 is couplable to a top surface 1716 of the PCB 1712 while the back plate 1714 is couplable to a bottom surface 1718 of the PCB 1712 opposite the bolster plate 1708. In this manner, the PCB 1712 is sandwiched between the bolster plate 1708 and the back plate 1714. The bolster plate 1708 is constructed to surround the socket 1710 positioned on the top surface 1716 of the PCB 1712.

The socket 1710 communicatively couples the IC package 1706 to the printed circuit board 1712. In FIG. 17, the socket 1710 is a land grid array (LGA) socket, which includes a plurality of pins within the socket arranged to interface (e.g., electrically couple) with corresponding contacts or lands on the IC package 1706. In other examples, the socket 1710 can be implemented by any other suitable type of socket (e.g., a ball grid array, a pin grid array, etc.) suitable to receive and interface with the IC package 1706. The compression created by the mechanical coupling of the heatsink 1702 to the back plate 1714 via the fasteners 1715 serves to ensure that corresponding connectors (e.g., pins, lands, etc.) on the socket 1710 and the IC package 1706 remain in contact.

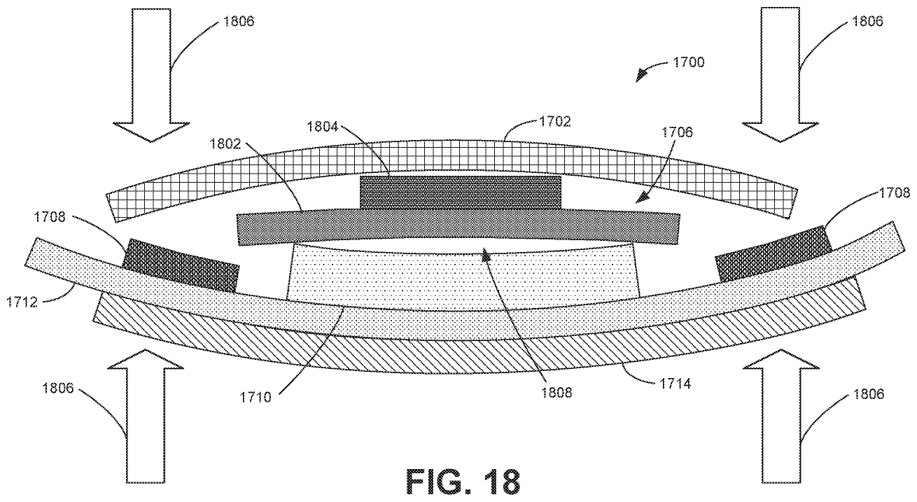

FIG. 18 is a simplified cross-sectional view of the heat dissipating component stack 1700 of FIG. 17. In FIG. 18, the component stack 1700 includes the heatsink 1702 of FIG. 17, the IC package 1706 of FIG. 17, the bolster plate 1708 of FIG. 17, the socket 1710 of FIG. 17, the printed circuit board 1712 of FIG. 17, and the back plate 1714 of FIG. 17 (the carrier 1704 of FIG. 17 is omitted in FIG. 18 for purposes of explanation). As shown in FIG. 18, the IC package 1706 includes a semiconductor substrate 1802 and an integrated heat spreader (IHS) 1804. The IHS 1804 is disposed adjacent the heatsink 1702 to conduct heat from the semiconductor substrate 1802 and into the heatsink 1702. In some instances, a thermal interface material (TIM) is disposed between the IHS 1804 and the heatsink 1702 to facilitate heat transfer therebetween.

As represented in FIG. 18, the tightening of the fasteners 1715 (shown in FIG. 17) causes a compressive force 1806 to be applied to the edges of the component stack 1700 (e.g., at the corners of the heatsink 1702 and the back plate 1714). The locations at which the compressive force 1806 acts on the component stack 1700 results in the components bending or warping as represented (in an exaggerated way) in FIG. 18. More particularly, as shown, the compressive force 1806 urges both the heatsink 1702 and the IC package 1706 to bend or curve in a first direction (e.g., downward in FIG. 18) toward the bolster plate 1708, the socket 1710, the PCB 172, and the back plate 1714. Similarly, the compressive force 1806 urges the bolster plate 1708, the socket 1710, the PCB 172, and the back plate 1714 to bend or curve in a second direction (e.g., upward in FIG. 18) toward the heatsink 1702 and the IC package 1706. Such bowing or warpage in the components can result in a gap or separation 1808 between the IC package 1706 and the socket 1710. The gap or separation 1808 is typically the greatest near a center of the IC package 1706 and the socket 1710 and can lead to insufficient contact between the connectors in the IC package 1706 and the socket 1710, thereby leading to degradation in performance of the IC package 1706 (if not rendering the IC package 1707 inoperable).

Warpage of components as represented in FIG. 18 can be reduced by increasing the strength and/or stiffness of the components. Specifically, examples disclosed herein involve an improved back plate that includes a ceramic (e.g., alumina) substrate, which is a stiffer material than what has been used in the past (e.g., steel). While ceramic materials provide greater stiffness than steel or other typical metals used in such applications, ceramics are much more likely to crack, fracture, or otherwise mechanically fail (particularly under shock loading). Accordingly, examples disclosed herein involve back plates that are predominantly ceramic to provide adequate stiffness to reduce warpage under the high loads from the compressive force 1806 but are reinforced by metal. While it may be possible to attach a sheet of metal to a ceramic plate, such an approach requires an adhesive to bond the layers together, which introduces extra processing operations and a potential point of failure. Further, using a sheet of metal adhered to a layer of ceramic limits the options in providing metal reinforcement to targeted areas where fractures, cracking, and/or crack propagation in the ceramic is most likely while increasing (e.g., maximizing) the amount of ceramic material used in other areas for increased stiffness. Specifically, crack or fracture formation and propagation typically occurs at features (e.g., holes, openings, etc.) within the back plate and/or near the edges of the back plate.

Examples disclosed herein improve upon known back plates through the fabrication of back plates that are predominantly (e.g., a majority by volume) ceramic but that include metal at targeted areas where fractures or cracks are likely to occur. Further, in examples disclosed herein, the metal is affixed to the ceramic without the use of an adhesive. More particularly, in some examples, the metal is shaped through a die casting process in which the shape of the ceramic portion of the back plate is disposed in the die cast mold. In other examples, the metal is embedded inside the ceramic material, which is possible by fabricating the ceramic material with its intended shape through a sintering process.

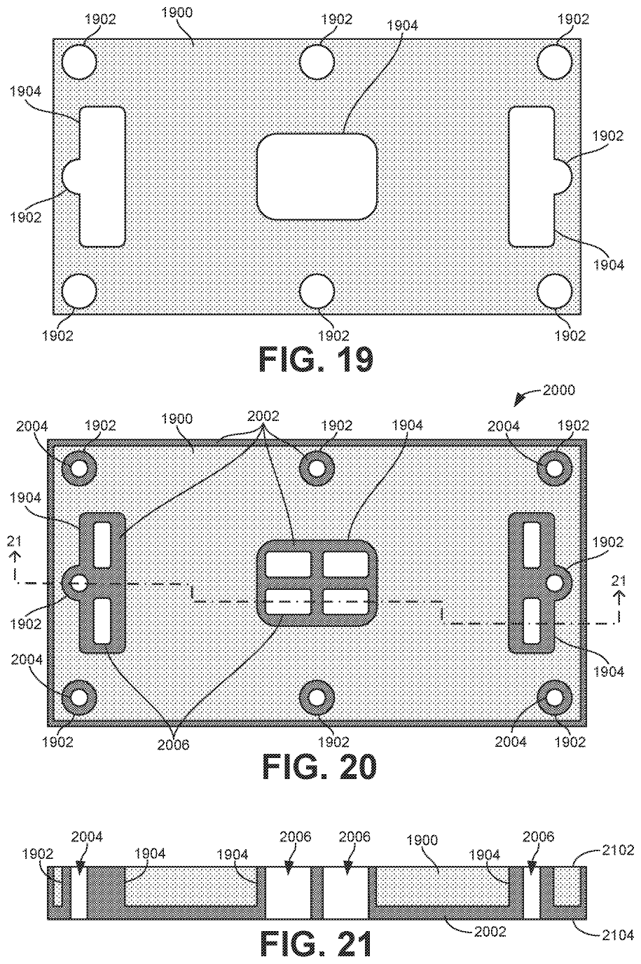

FIG. 19 illustrates an example ceramic substrate 1900 for a back plate 2000 illustrated in FIG. 20. FIG. 21 is a cross-sectional view of the back plate of FIG. 21 taken along the line 21-21 shown in FIG. 20. In this example, the ceramic substrate 1900 is composed of alumina (e.g., aluminum oxide). However, any other suitable ceramic can be employed. In some examples, the ceramic substrate 1900 is fabricated through a sintering process in which particles of the ceramic material (e.g., alumina) are compressed or compacted together with relatively high pressure at relatively high temperatures to form a solid mass based on fusion bonds between the particles. While sintering results in a solid mass, the mass typically has a relatively rough surface with visible grains corresponding to individual particulars of the material fused together. The sintering temperature is less than the melting temperature of the material being sintered. For example, alumina has a melting point of approximately 2050° C. However, alumina can be sintered at a temperature between approximately 1500° C. and 1800° C.

Sintering enables the resulting solid mass to have any suitable shape. For instance, in the illustrated example, the ceramic substrate includes round holes 1902 at locations where fasteners are used to attach the resulting back plate 2000 to other components within the heat dissipating component stack 1700 as discussed further below. Additionally, in this example, the ceramic substrate 1900 includes rectangular openings 1904 that provide space for capacitors on the bottom surface 1718 of the PCB 1712 to stick through the back plate 2000. The terms “holes” and “openings” are separately used to distinguish between the different purposes of such as outlined above. However, this is for purposes of explanation and such terms should not be limited to only the purpose specified above. Thus, any of the holes described herein can properly be referred to as openings. Likewise, any of the openings described herein can properly be referred to as holes. In some examples, the holes 1902 and/or the openings 1904 can have sizes, shapes, and/or locations other than what is shown in FIG. 19 depending on the intended application or use for the back plate 2000 and the associated holes and/or openings. Further, in some examples, there may be more or fewer holes 1902 and/or openings 1904 than what is shown in FIG. 19 depending on the intended application or use for the back plate 2000 and the associated holes and/or openings.

In some examples, features such as the holes 1902 and the openings 1904 in the ceramic substrate 1900 can provide failure points at which cracks and/or fractures can arise, particularly under shock loads. Accordingly, in some examples, the holes 1902 and openings 1904 are dimensioned to be larger than necessary for the final back plate 2000 to then be partially filled by metal 2002 as shown in FIG. 20. Thus, as shown in FIG. 20, the metal 2002 (also referred to herein as a metal frame) defines final (smaller) holes 2004 within the initial holes 1902 of the ceramic substrate 1900 and defines final (smaller) openings 2006 within the initial openings 1904 within the ceramic substrate 1900. The metal 2002 lines the holes 1902 and openings 1904 to reinforce and/or strengthen the ceramic material and to reduce the onset and/or propagation of cracks within the ceramic substrate 1900. Thus, the metal 2002 is an example means for reinforcing the ceramic substrate 1900. In some examples, as shown, more than one final hole 2004 and/or more than one final opening 2006 can be defined within a single one of the initial holes 1902 and/or initial openings 1904 in the ceramic substrate 2200. In some examples, one or more of the final holes 2004 are provided within ones of the initial openings 1904 (rather than within a particular initial hole 1902). Further, in some examples, the final holes 2004 and/or the final openings 2006 can have sizes, shapes, and/or locations other than what is shown in FIG. 20 depending on the intended application or use for the back plate 2000 and the associated holes and/or openings. Further, in some examples, there may be more or fewer holes 2004 and/or openings 2006 than what is shown in FIG. 20 depending on the intended application or use for the back plate 2000 and the associated holes and/or openings.

In some examples, the metal 2002 is formed to the shape shown in FIGS. 20 and 21 through a die casting process. More particularly, in some examples, the ceramic substrate 1900 is fabricated first. Then the ceramic substrate 1900 is disposed within a die cast mold with extra space surrounding the ceramic substrate 1900 to be filled by the metal 2002 during the casting process. In this manner, the metal 2002 can be integrally connected to the ceramic substrate 1900 without an adhesive or other intermediate material. More particularly, no adhesive is needed and a relatively strong bond between the materials can be achieved because of the relatively rough or granular surface of the ceramic substrate 1900 resulting from the sintering process used to fabricate the ceramic substrate 1900. That is, during the casting process, the metal flows into cavities, voids, or openings in the granular surface between separate grains of the sintered ceramic material to provide a strong mechanical bond. In some examples, an adhesive or other intermediate material may still be used between at least some portions (or all) of the ceramic substrate 1900 and the metal 2002. In some such examples, the adhesive or other intermediate material is applied to the surface of the ceramic substrate 1900 before the ceramic substrate 1900 is inserted into a die cast mold. In some examples, the metal 2002 is steel. However, any other suitable metal may additionally or alternatively be used. More particularly, any metal can be used that has a melting point lower than the ceramic material so that the die casting process can be completed without melting the ceramic substrate 1900.

In some examples, as shown in FIG. 20, an outer perimeter of the back plate 2000 (defined by lateral surfaces extending between a first (top) surface 2102 and a second (bottom) surface of the back plate 2000) is covered by the metal 2002. This is to facilitate the die casting process with the ceramic substrate 1900 disposed within the mold. However, in other examples, some or all of the lateral surfaces of the ceramic substrate 1900 may be exposed or uncovered by the metal 2002. In some examples, this is accomplished based on the design and shape of the die cast mold used for the metal 2002 in conjunction with the design and shape of the ceramic substrate 1900 and its placement within the mold during the casting process. Additionally or alternatively, in some examples, the exposure of the ceramic substrate 1900 along the outer perimeter of the back plate 2000 is achieved by removing the metal 2002 after the casting process.

Further, as shown in the illustrated example, the metal 2002 extends the distance between the first and second surfaces 2102, 2104 of the back plate 2000 within and along the walls of the holes 1902 and openings 1904 of the ceramic substrate 1900. Thus, in some examples, portions of the metal 2002 are circumferentially surrounded by the ceramic substrate 1900. Stated differently, in some examples, portions of the metal 2002 are disposed between planes defined by the first and second surfaces 2102, 2104 and positioned laterally adjacent to the holes. In the illustrated example, the metal 2002 covers the entire second (bottom) surface 2104 of the back plate 2000 (except for the holes 2004 and openings 2006). However, in other examples, the ceramic substrate 1900 may extend a full distance between the first and second surfaces 2102, 2104. That is, in some examples, the ceramic substrate 1900 is exposed on the second surface 2104 (in addition to on the first surface 2102). In some examples, this is accomplished based on the design and shape of the die cast mold used for the metal 2002 in conjunction with the design and shape of the ceramic substrate 1900 and its placement within the mold. Additionally or alternatively, in some examples, the exposure of the ceramic substrate 1900 along the second (bottom) surface 2104 of the back plate 2000 is achieved by removing the metal 2002 after the casting process.

As described above, the purpose of the ceramic substrate 1900 is to provide greater stiffness to resist bending or warpage due to the compressive force 1806 associated with the assembled heat dissipating component stack 1700. Thus, the ceramic substrate 1900 is an example means for stiffening a back plate. The ceramic substrate 1900 achieves this purpose due to the fact that the ceramic substrate has a greater stiffness than the metal 2002. To increase (e.g., maximize) the advantage of the greater stiffness provided by the ceramic substrate 1900, in some examples, the back plate 2000 is predominantly ceramic. That is, in some examples, the volume of the ceramic substrate 1900 within the back plate 2000 is greater than the volume of the metal 2002. As a result, as shown in FIG. 21, the thickness of the ceramic substrate 1900 is greater than the thickness of the metal 2002 along the bottom surface 2104.

While the ceramic substrate 1900 has a greater stiffness than the metal 2002, the ceramic is more likely to crack or fracture. Further, such mechanical failures are particularly likely to occur near the holes 1902 and openings 1904. However, the metal 2002 provided at these locations can reduce this likelihood by reinforcing the ceramic substrate 2002 around the holes 1902 and the openings 1904. In some examples, the metal 2002 can also help facilitate the mounting or attaching of the back plate 2000 to other components in the component stack 1700. For instance, in some examples, the final holes 2004 are threaded to enable a threaded fastener (e.g., a screw, a bolt, etc.) to be inserted therein. Adding threads to holes in metal is much easier than adding threads to holes in a ceramic. Furthermore, threads in a ceramic would provide an even more likely location for cracks to form and/or propagate. Thus, the metal 2002 within the initial holes 1902 in the ceramic substrate 1900 can facilitate different mechanisms for fastening the back plate 2000 to other components that would not otherwise be possible. In some examples, the final holes 2004 do not include threads but are dimensioned to permit a threaded fastener to extend therethrough.

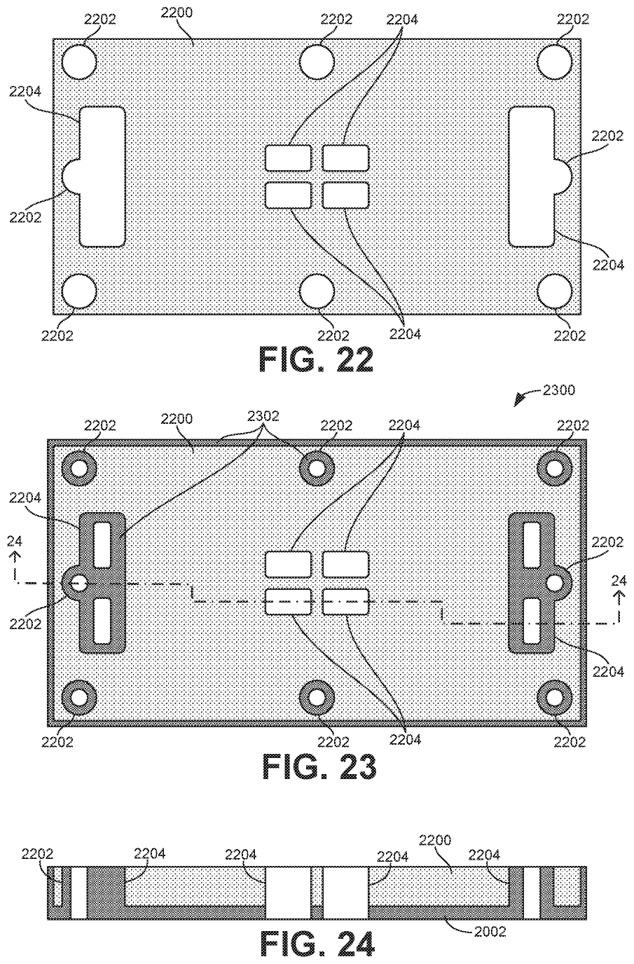

Many variations to the back plate 2000 shown and described in connection with FIGS. 19-21 are possible. For instance, FIGS. 22-24 illustrate another example back plate 2300 constructed in accordance with teachings disclosed herein. More particularly, FIG. 22 illustrates another example ceramic substrate 2200 to be integrated with metal 2302 (via a casting process) to form the back plate 2300 shown in FIGS. 23 and 24. The ceramic substrate 2200 is an example means for stiffening a back plate. The metal 2302 is an example means for reinforcing the ceramic substrate 2200. In this example, the ceramic substrate 2200 includes holes 2202 and openings 2204 that are similar to the holes 1902 and openings 1904 described in connection with FIG. 19. However, rather than having a large central opening 1904 (as in FIG. 19), in the illustrated example of FIG. 22, four openings 2204 are provided that are dimensioned similarly to the final openings 2006 described above in connection with FIG. 20. Thus, when the metal 2302 is added, as illustrated in FIG. 23, these four central openings 2204 are not lined with metal but having exposed inner walls composed of ceramic material. Thus, in some examples, at least some openings and/or holes within the ceramic substrate 2200 may not include metal disposed therein.

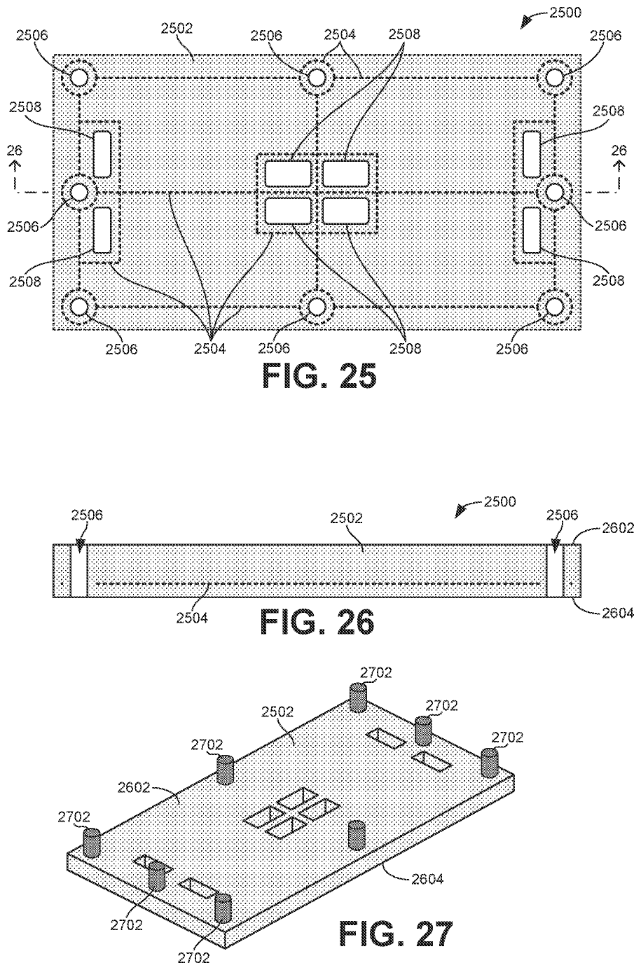

FIG. 25 illustrates another example back plate 2500 constructed in accordance with teachings disclosed herein. FIG. 26 is a cross-sectional view of the example back plate 2500 of FIG. 25 taken along the line 26-26 of FIG. 25. In the illustrated example of FIGS. 25 and 26, the back plate 2500 is defined by a ceramic substrate 2502 with metal wire 2504 embedded therein. The ceramic substrate 2502 is an example means for stiffening a back plate. The metal wire 2504 is an example means for reinforcing the ceramic substrate 2502. In some examples, the metal wire 2504 is disposed or embedded within the ceramic substrate 2502 during the sintering process (e.g., before the ceramic particles are fused together under heat and pressure). In some examples, to ensure the metal wire 2504 remains intact during the sintering process, the material used for the metal wire 2504 is a metal with a melting point above the sintering temperature of the ceramic material (e.g., above 1800° C. for alumina). Some such metals include tungsten, rhenium, nitinol, and Inconel 718. Other relatively high melting point metals may additionally or alternatively be used. Some such metals have a stiffness that is even higher than alumina and, therefore, can contribute to the stiffness of the back plate 2500. However, in some examples, the bulk of the back plate 2500 corresponds to the ceramic material because of the relatively high costs of high melting point metals.

As shown in FIG. 25, the ceramic substrate 2502 includes holes 2506 and openings 2508 that are similar in dimension and placement to the final holes 2004 and final openings 2006 described in connection with FIG. 20. That is, similar to the central openings 2204 in the ceramic substrate 2200 of FIG. 2, the holes 2506 and openings 2508 in the back plate 2500 of FIGS. 25 and 26 are not lined with metal. However, these features are reinforced or strengthened by the metal wire 2504 that partially or completely surround or loop the holes 2004 and openings 2006. As a result, the likelihood of crack formation and/or propagation is reduced. In this example, different portions of the metal wire 2504 that loop around the holes 2506 and openings 2508 are connected by elongate strands of the metal wire 2504 extending therebetween. However, in other examples, different portions of the metal wire 2504 can be isolated from one another. That is, the elongate lengths of the metal wire 2504 may be omitted.

Further, in some examples, only some of the holes 2506 and/or openings 2508 are surrounded by the metal wire 2504. In some examples, ones of the holes 2506 and/or openings 2508 may be surrounded by more than one loop of the metal wire 2504 (e.g., at different distances from the holes 2506 and/or openings 2508). In some examples, the metal wire 2504 is a mesh that is distributed across the solid portions of the ceramic substrate 2502 (e.g., the portions where there are no holes 2506 and no openings 2508). In some examples, the wire mesh is relatively evenly distributed. In other examples, the wire mesh is more densely distributed at locations of relatively high stress where crack formation and/or propagation is more likely. In some examples, different thickness of wire are used at different locations within the ceramic substrate 2502 (e.g., thicker wire near higher stress areas). In some examples, strips of metal can be used in addition to or instead of the metal wire 2504 to provide strength and/or increased stiffness to the back plate 2500.

As shown in FIG. 26, in this example, the metal wire 2504 is positioned closer to the second (bottom) surface 2604 of the back plate 2500 than the metal wire 2504 is to the first (top) surface 2602 of the back plate 2500. In other examples, the metal wire 2504 is closer to the top surface 2602 than to the bottom surface 2604. In other examples, the metal wire 2504 is positioned approximately in the center of the back plate 2500. In some examples, multiple (e.g., two or more) layers of the metal wire 2504 can be located at different depths within the thickness of the back plate 2500. In some such examples, the metal wire 2504 in a first layer may be located in particular areas within the back plate 2500 while the metal wire 2504 in a second layer is located in different areas (and/or distributed to additional areas beyond the particular areas of the metal wire 2504 in the first layer).

As discussed above, it can be difficult to add threads to holes in ceramic materials. Thus, in some examples, the holes 2506 in the ceramic substrate 2502 of FIGS. 25 and 26 do not include threads. Instead, the holes 2506 are dimensioned to receive a stud or male threaded fastener 2702 that protrudes away from the top surface 2602 of the ceramic substrate 2502 as shown in FIG. 27. In some examples, the studs 2702 are maintained affixed within the holes 2506 with an adhesive. Additionally or alternatively, in some examples, the studs 2702 are maintained within the holes 2506 using a mechanical stop (e.g., a bolt head, a screw head, a nut, etc.) that engages or interfaces with the bottom surface 2604 of the ceramic substrate 2502.

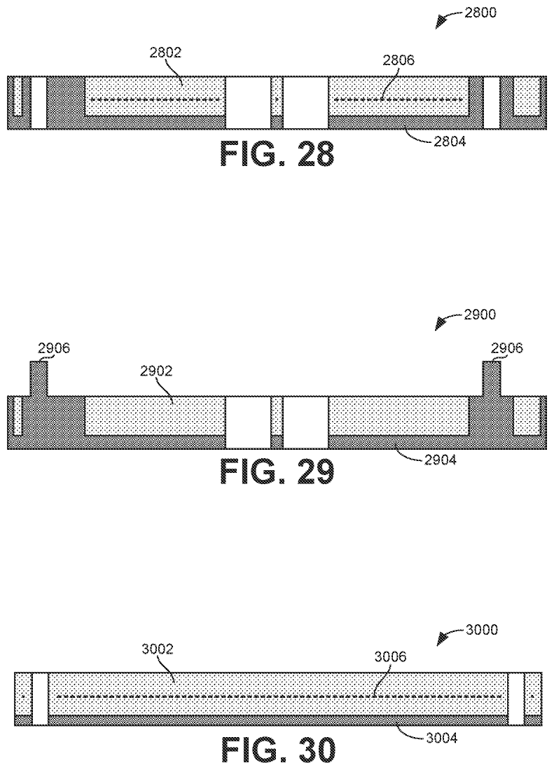

In some examples, the embedded metal wire 2504 in the back plate 2500 of FIGS. 25 and 26 can be used in combination with the die cast metal 2002, 2302 shown in the example back plates 2000, 2300 of FIGS. 19-24. That is, the example back plates 2000, 2300, 2500 are not mutually exclusive but any of the features or aspects shown and described in any one of the examples disclosed herein can be used in combination with and/or replace the features and/or aspects shown in any of the other examples disclosed herein. For instance, FIG. 28 is a cross-sectional view of another example back plate 2800 that includes a ceramic substrate 2802 integrally formed with a mechanically supportive metal frame 2804 (similar to FIGS. 19-24) where the ceramic substrate 2802 includes mechanically supportive metal wire 2806 embedded therein (similar to FIGS. 25 and 26). The ceramic substrate 2802 is an example means for stiffening a back plate. Both the metal frame 2804 and the metal wire 2806 are example means for reinforcing the ceramic substrate 2802.

Further, in some examples, studs similar to the studs 2702 shown and described in FIG. 27 can be incorporated into the metal frame fabricated in the die casting process. For instance, FIG. 29 is a cross-sectional view of another example back plate 2900 that includes a ceramic substrate 2902 integrally formed with a mechanically supportive metal frame 2904 similar to FIGS. 19-24. However, instead of the metal frame 2904 including the final holes 2004, the metal of the metal frame 2904 completely fills the initial holes within the ceramic substrate 2902 and further includes protrusions or studs 2906 integrally formed and extending therefrom. In some such examples, the studs 2906 are threaded to facilitate the fastening of the back plate 2900 to other components in the IC package heat dissipating component stack 1700. The ceramic substrate 2902 is an example means for stiffening a back plate. The metal frame 2904 is an example means for reinforcing the ceramic substrate 2902.

Further, in some examples, any of the example back plates 2000, 2300, 2500, 2800, 2900 disclosed herein can be bonded to a sheet or plate of metal (e.g., using an adhesive) to provide additional strength and/or stiffness to the back plates. For instance, FIG. 30 is a cross-sectional view of another example back plate 3000 that includes a ceramic substrate 3002 with a sheet or plate of metal 3004 bonded (e.g., with an adhesive) thereto and with mechanically supportive metal wire 3006 embedded therein. In this example, the sheet of metal 3004 is attached to a bottom surface of the ceramic substrate 3002. In other examples, the sheet of metal 3004 is attached to the top surface of the ceramic substrate 3002. In some examples, separate sheets of metal 3004 may be attached to both the top and bottom surfaces of the ceramic substrate 3002. While the sheet of metal 3004 is shown as being coextensive with the ceramic substrate 3002, in other examples, the sheet of metal 3004 covers less than all of the interfacing surface of the ceramic substrate 3002. In some examples, the sheet of metal 3004 may be divided into more than one distinct region on the interfacing surface of the ceramic substrate 3002. The ceramic substrate 3002 is an example means for stiffening a back plate. Both the sheet of metal 3004 and the metal wire 3006 are example means for reinforcing the ceramic substrate 3002.

Additionally or alternatively, the sheet of metal 3004 can be bonded to a ceramic substrate that already has metal coupled thereto as part of a die casting process. Thus, the sheet of metal 3004 can be bonded to anyone of the example back plates 2000, 2300, 2500, 2800, 2900 on the bottom surface, the top surface, or both. As a result, in some examples, a back plate disclosed herein may include a first metal that is coupled to a ceramic substrate without an adhesive (e.g., based on a die casting process and/or embedding the metal within the ceramic substrate prior to a sintering process) and include a second metal that is coupled to the ceramic substrate with an adhesive.

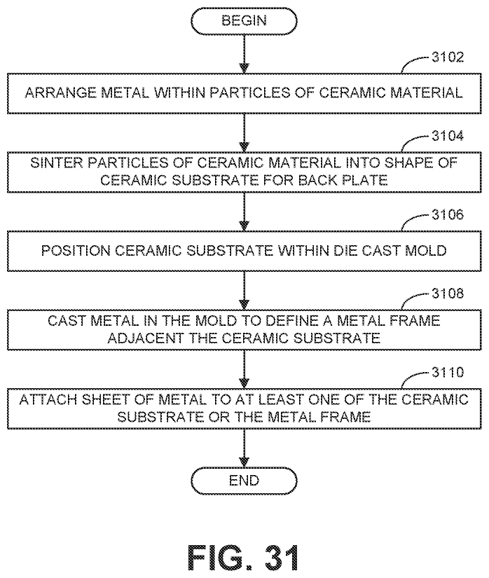

FIG. 31 is a flowchart representative of an example method of manufacturing any one of the example back plates 1900, 2300, 2500, 2800, 2900, 3000 disclosed herein. Although the example method of manufacture is described with reference to the flowchart illustrated in FIG. 31, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example process begins at block 3102 by arranging metal within particles of ceramic material. In some examples, the metal includes wires, wire meshes, and/or metal strips. In some examples, block 3102 is omitted. At block 3104, the process involves sintering the particles of ceramic material into a shape of a ceramic substrate for a back plate. At block 3106, the process involves positioning the ceramic substrate within a die cast mold. At block 3108, the process involves casting metal in the mold to provide a metal frame adjacent the ceramic substrate. In some examples, blocks 3106 and 3108 are omitted. At block 3110, the process involves attaching a sheet of metal to at least one of the ceramic substrate or the metal frame. In some examples, block 3110 is omitted. Thereafter, the example process of FIG. 31 ends.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, methods, apparatus, and articles of manufacture have been disclosed that increase the structural integrity of back plates for use in IC package heat dissipating component stacks. More particularly, example back plates disclosed herein are a composite of ceramic material and metal. The ceramic material provides stiffness that can resist bending or warpage of the back plate when subject to applied loads. The metal serves to reinforce the ceramic material so as to reduce the onset and/or propagation of cracks therein.

Further examples and combinations thereof include the following:

Example 1 includes a back plate comprising a ceramic substrate having a first surface and a second surface opposite the first surface, and metal coupled to the ceramic substrate, at least a portion of the metal disposed between planes defined by the first and second surfaces of the ceramic substrate.

Example 2 includes the back plate of example 1, wherein the ceramic substrate includes sintered alumina.

Example 3 includes the back plate of any one of examples 1 or 2, wherein there is no adhesive between the ceramic substrate and the metal.

Example 4 includes the back plate of any one of examples 1-3, wherein the metal is adjacent the second surface of the ceramic substrate.

Example 5 includes the back plate of example 4, wherein the metal is to cover the second surface of the ceramic substrate.

Example 6 includes the back plate of any one of examples 4 or 5, wherein the metal is to cover lateral surfaces of the ceramic substrate, the lateral surfaces to extend between the first and second surfaces of the ceramic substrate.

Example 7 includes the back plate of any one of examples 1-6, wherein the ceramic substrate includes a hole extending therethrough.

Example 8 includes the back plate of example 7, wherein the metal is to extend through the hole.

Example 9 includes the back plate of example 8, wherein the metal is to extend along a wall of the hole to define a smaller hole extending therethrough.

Example 10 includes the back plate of example 9, wherein the smaller hole is threaded.

Example 11 includes the back plate of any one of examples 8-10, wherein the ceramic substrate includes an opening extending through the ceramic substrate, the metal not extending through the opening.

Example 12 includes the back plate of any one of examples 7-11, wherein the metal is embedded within the ceramic substrate, the metal surrounding the hole.

Example 13 includes the back plate of example 12, wherein the metal includes at least one of a metal wire, a wire mesh, or a metal strip.

Example 14 includes the back plate of any one of examples 12 or 13, wherein a melting point of the metal is higher than a sintering temperature of a material included in the ceramic substrate.

Example 15 includes an apparatus comprising a bolster plate, and a back plate, the back plate to connect to the bolster plate to sandwich a circuit board therebetween, the back plate including a ceramic substrate and metal coupled to the ceramic substrate without an adhesive.

Example 16 includes the apparatus of example 15, wherein the back plate includes a first surface to face toward the bolster plate and a second surface to face away from the bolster plate, the metal extending a distance between the first and second surfaces of the back plate.

Example 17 includes the apparatus of example 16, wherein the metal extends between the first and second surfaces of the back plate along walls of a hole in the ceramic substrate.

Example 18 includes the apparatus of any one of examples 15-17, wherein the ceramic substrate includes two opposing surfaces, the metal disposed within the ceramic substrate spaced apart from both of the opposing surfaces.

Example 19 includes an apparatus comprising means for stiffening a back plate to resist warpage from a force applied to the back plate when assembled in an integrated circuit package heat dissipating component stack, the stiffening means including a hole extending therethrough, and means for reinforcing the stiffening means adjacent the hole, portions of the reinforcing means circumferentially surrounded by the stiffening means.

Example 20 includes the apparatus of example 19, wherein the hole is a first hole, the stiffening means including a second hole, the reinforcing means closer to the first hole than to the second hole.

Example 21 includes the apparatus of example 19, wherein the reinforcing means is disposed within the hole.

Example 22 includes the apparatus of example 19, wherein the reinforcing means is spaced apart from and surrounds the hole.

Example 23 includes a method comprising sintering particles of a ceramic material to define a ceramic substrate, and coupling metal to the ceramic substrate without an adhesive.

Example 24 includes the method of example 23, wherein the coupling of the metal to the ceramic substrate includes arranging the metal within the particles before the sintering.

Example 25 includes the method of any one of examples 23 or 24, wherein the coupling of the metal to the ceramic substrate includes positioning the ceramic substrate within a die cast mold, and casting the metal within spaces within the die cast mold surrounding the ceramic substrate.

Example 26 includes the method of any one of examples 23-25, wherein the ceramic material and the metal collectively define a back plate, the method further including coupling the back plate to a circuit board opposite a socket, the back plate to reduce warpage of the socket to improve electrical contact between the socket and IC package.

Example 27 includes the method of any one of examples 23-26, wherein the metal provides structural support to the ceramic material to reduce at least one of crack formation or crack propagation within the ceramic material.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. A back plate comprising:
a ceramic substrate having a first surface and a second surface opposite the first surface; and
metal coupled to the ceramic substrate, at least a portion of the metal disposed between planes defined by the first and second surfaces of the ceramic substrate.

2. The back plate of claim 1, wherein the ceramic substrate includes sintered alumina.

3. The back plate of claim 1, wherein there is no adhesive between the ceramic substrate and the metal.

4. The back plate of claim 1, wherein the metal is adjacent the second surface of the ceramic substrate.

5. The back plate of claim 4, wherein the metal is to cover the second surface of the ceramic substrate.

6. The back plate of claim 4, wherein the metal is to cover lateral surfaces of the ceramic substrate, the lateral surfaces to extend between the first and second surfaces of the ceramic substrate.

7. The back plate of claim 1, wherein the ceramic substrate includes a hole extending therethrough.

8. The back plate of claim 7, wherein the metal is to extend through the hole.

9. The back plate of claim 8, wherein the metal is to extend along a wall of the hole to define a smaller hole extending therethrough.

10. The back plate of claim 9, wherein the smaller hole is threaded.

11. The back plate of claim 8, wherein the ceramic substrate includes an opening extending through the ceramic substrate, the metal not extending through the opening.

12. The back plate of claim 7, wherein the metal is embedded within the ceramic substrate, the metal surrounding the hole.

13. The back plate of claim 12, wherein the metal includes at least one of a metal wire, a wire mesh, or a metal strip.

14. The back plate of claim 12, wherein a melting point of the metal is higher than a sintering temperature of a material included in the ceramic substrate.

15. An apparatus comprising:
a bolster plate; and
a back plate, the back plate to connect to the bolster plate to sandwich a circuit board therebetween, the back plate including a ceramic substrate and metal coupled to the ceramic substrate without an adhesive.

16. The apparatus of claim 15, wherein the back plate includes a first surface to face toward the bolster plate and a second surface to face away from the bolster plate, the metal extending a distance between the first and second surfaces of the back plate.

17. The apparatus of claim 16, wherein the metal extends between the first and second surfaces of the back plate along walls of a hole in the ceramic substrate.

18. The apparatus of claim 15, wherein the ceramic substrate includes two opposing surfaces, the metal disposed within the ceramic substrate spaced apart from both of the opposing surfaces.

19. An apparatus comprising:
means for stiffening a back plate to resist warpage from a force applied to the back plate when assembled in an integrated circuit package heat dissipating component stack, the stiffening means including a hole extending therethrough; and
means for reinforcing the stiffening means adjacent the hole, portions of the reinforcing means circumferentially surrounded by the stiffening means.

20. The apparatus of claim 19, wherein the hole is a first hole, the stiffening means including a second hole, the reinforcing means closer to the first hole than to the second hole.

21. The apparatus of claim 19, wherein the reinforcing means is disposed within the hole.

22. The apparatus of claim 19, wherein the reinforcing means is spaced apart from and surrounds the hole.

23. A method comprising:
sintering particles of a ceramic material to define a ceramic substrate; and
coupling metal to the ceramic substrate without an adhesive.

24. The method of claim 23, wherein the coupling of the metal to the ceramic substrate includes arranging the metal within the particles before the sintering.

25. The method of claim 23, wherein the coupling of the metal to the ceramic substrate includes:
positioning the ceramic substrate within a die cast mold; and
casting the metal within spaces within the die cast mold surrounding the ceramic substrate.
